(19) United States
(12) Patent Application Publication
(10) Pub. No.: US 2010/0002391 A1
(43) Pub. Date: Jan. 7, 2010

(54) ELECTRONIC DEVICE WITH HEAT SINK ASSEMBLY

(75) Inventors: YU-LING JIANG, Shenzhen City (CN); ZHI-JIANG YAO, Shenzhen City (CN); NING-YU WANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO.,LTD., Shenzhen City (CN); HON HAI PRECISION INDUSTRY CO., LTD., Tu-Cheng (TW)

(21) Appl. No.: 12/240,031

(22) Filed: Sep. 29, 2008

(30) Foreign Application Priority Data
Jul. 1, 2008 (CN) 200820301398.2

(51) Int. Cl. H05K 7/20

(52) U.S. Cl. 361/697

(57) ABSTRACT

An electronic device includes a first heat source, a second heat source adjacent to the first heat source, a heat sink, and a fan. The heat sink is mounted on the first heat source for transferring heat from the first heat source to the heat sink. The fan has an air inlet and an air outlet. The air outlet faces the second heat source to drive air flowing through the second heat source if the air inlet faces the heat sink. The air outlet faces the heat sink to drive air flowing through the heat sink if the air inlet faces the second heat source.

### BACKGROUND

1. Technical Field

The present invention relates to an electronic device with a heat sink assembly mounted thereon.

2. Description of Related Art

Computers usually have a plurality of different operating components mounted therein. In recent years, the heat generated from these operating components has risen dramatically as the operating components have become more sophisticated. Each operating component often requires its own dedicated heat sink to dissipate heat. Thus, these heat sinks occupy a large amount of space. In addition, smaller personal computers, which have limited interior space have become popular, making heat sinks a burden in the design process.

Therefore, a small and efficient heat sink assembly is desired to overcome the above-described deficiency.

### BRIEF DESCRIPTION OF THE DRAWINGS

FIG. 1 is an exploded, isometric view of an embodiment of an electronic device with a heat sink assembly which includes a fan and a heat sink.

FIG. 2 is an isometric view of the fan of FIG. 1.

FIG. 3 is an assembled, isometric view of the electronic device of FIG. 1.

### DETAILED DESCRIPTION OF THE EMBODIMENTS

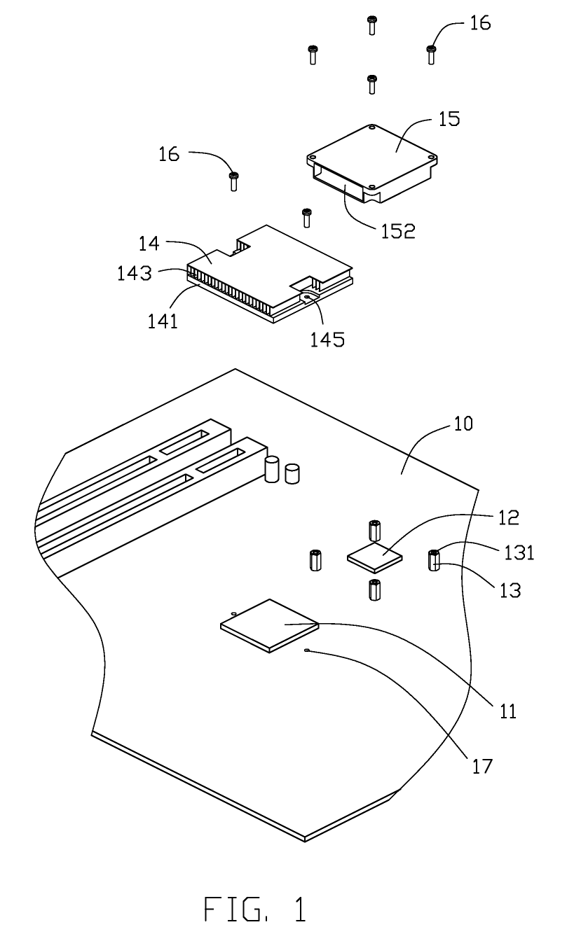

Referring to FIG. 1, an electronic device includes a circuit board 10 and a heat sink assembly configured for being mounted on the circuit board 10. The heat sink assembly includes a heat sink 14 and a fan 15.

A first heat source 11 and a second heat source 12 are mounted adjacent to each other on the circuit board 10. In this embodiment, the heat generated by the first heat source 11 is greater than that generated by the second heat source 12. For example, the first heat source 11 may be a CPU and the second heat source 12 may be a north bridge chipset. The circuit board 10 defines a pair of screw holes 17 in the circuit board 10 at opposite sides of the first heat source 11. The circuit board 10 is equipped with four posts 13 near four corners of the second heat source 12. Each post 13 defines a screw hole 131 therein.

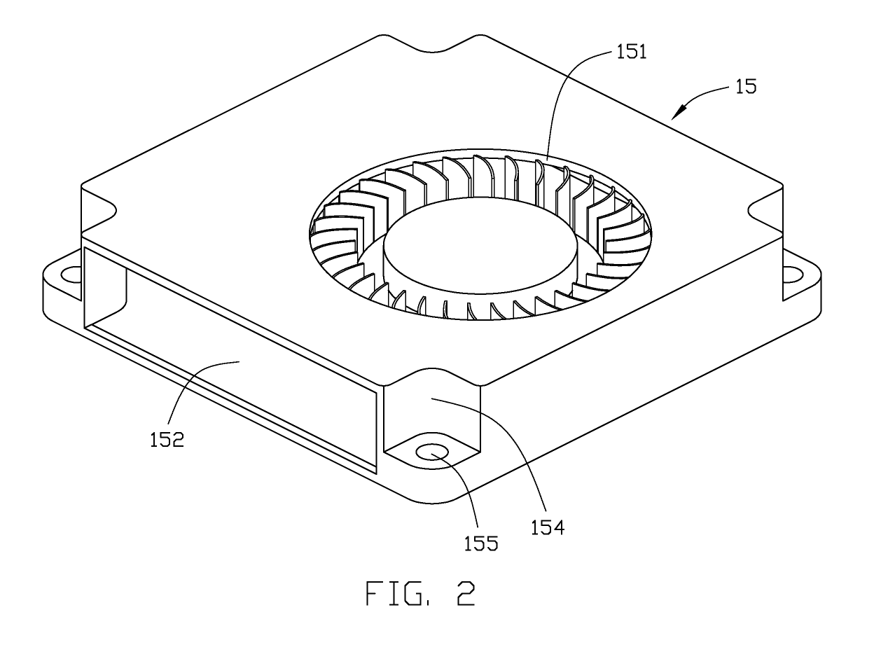

Referring also to FIG. 2, the fan 15 includes an air inlet 151 and an air outlet 152. The air inlet 151 and the air outlet 152 are defined in adjacent sides of the fan 15, so a first direction of air flowing into the air inlet 151 is substantially perpendicular to a second direction of air flowing out of the air outlet 152. In one embodiment, the first direction is a vertical direction perpendicular to the circuit board 10, and the second direction is a horizontal direction parallel to the circuit board 10. The fan 15 defines four cutouts 154 at four corners thereof configured for receiving the posts 13 therein. The fan 15 defines a screw hole at the bottom of each cutout 154 corresponding to the screw hole 131 of each of the posts 13.

The heat sink 14 includes a base 141 and a plurality of fins 143 extending from a top surface of the base 141. The fins of the plurality of fins 143 are substantially parallel and aligned in the second direction. The heat sink 14 defines a pair of mounting holes 145 corresponding to the screw holes 17 of the circuit board 10.

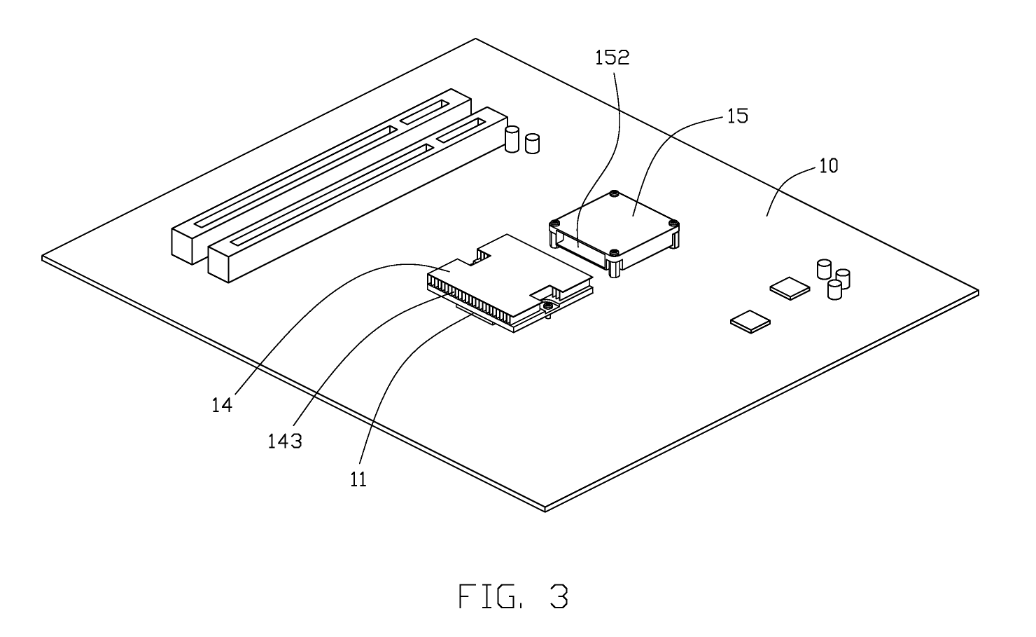

Referring to FIGS. 1 and 3, in assembly, the base 141 of the heat sink 14 is tightly contacting the first heat source 11. The mounting holes 145 of the heat sink 14 are aligned with the screw holes 17 of the circuit board 10. Two screws 16 are inserted into the mounting holes 145 and engaged with the screw holes 17 to mount the heat sink 14 to the circuit board 10. The fan 15 is placed on the posts 13 with the air outlet 152 facing the heat sink 14 and the air inlet 151 facing the second heat source 12. Top ends of the posts 13 are received in the cutouts 154 of the fan 15 and the screw holes 155 of the fan 15 are aligned with the screw holes 131 of the posts 13. Four screws 16 are then inserted into the screw holes 155 of the fan 15 and engaged with the screw holes 131 of the posts 13 to mount the fan 15 on top of the posts 13. With the fan 15 in this position, the air outlet 152 of the fan 15 and the fins 143 of the heat sink 14 are located at an approximately same height.

When the computer is operating, the first and second heat sources 11, 12 generate heat. The heat generated by the first heat source 11 is transferred to the heat sink 14. When the fan 15 is operating, air is drawn from the second heat source 12 into the air inlet 151 out through the air outlet 152, and flows through the fins 143 of the heat sink 14. Therefore, the heat from the second heat source 12 and the fins 143 is dissipated by the air flowing therethrough. Since the fins 143 are aligned in the same direction as the air outlet 152, the heat on the fins 14 is dissipated very quickly.

In another embodiment, the fan 15 can be mounted above the heat sink 14 so that the air inlet 151 faces the heat sink 14 and the air outlet 152 faces the second heat source 12.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device comprising:
a first heat source and a second heat source adjacent to the first heat source;
a heat sink mounted on the first heat source for transferring heat from the first heat source to the heat sink; and
a fan having an air inlet and an air outlet, wherein the air outlet faces the second heat source to drive air flowing through the second heat source if the air inlet faces the heat sink; the air outlet faces the heat sink to drive air flowing through the heat sink if the air inlet faces the second heat source.

2. The electronic device of claim 1, wherein the air inlet and the air outlet are defined in adjacent sides of the fan; a first direction of driving air flowing into the air inlet is substantially perpendicular to a second direction of driving air flowing out of the air outlet.

3. The electronic device of claim 2, further comprising a circuit board, wherein the first and second heat sources are attached to the circuit board; the first direction is perpendicular to the circuit board.

4. The electronic device of claim 2, wherein the air inlet faces the second heat source and the air outlet faces the heat sink.

5. The electronic device of claim 4, wherein the heat sink comprises a plurality of parallel fins aligned in the second direction; the fan drives air flowing through the fins.

6. The electronic device of claim 4, wherein heat generated by the first heat source is greater than heat generated by the second heat source.

7. The electronic device of claim 1, further comprising four posts, wherein the fan defines four cutouts at four corners of the fan, the four cutouts receive the four posts to fix the fan to the posts.

8. The electronic device of claim 7, wherein the fan defines a screw hole on a bottom of each cutout; each post defines a screw hole aligned with each corresponding screw hole of the fan.

9. An electronic device comprising:
a circuit board comprising a first heat source and a second heat source attached thereon;
a fan mounted on the second heat source, the fan having an air inlet and an air outlet, wherein the air inlet faces the second heat source to guide air flowing from the second heat source in a first direction; and
a heat sink mounted on the first heat source for transferring heat from the first heat source to the heat sink, the heat sink comprising a plurality of parallel fins aligned in a second direction, wherein the second direction is different from the first direction; the air outlet of the fan faces the fins to guide air flowing through the fins in the second direction.

10. The electronic device of claim 9, wherein the air inlet and the air outlet are defined in adjacent sides of the fan; the first direction is perpendicular to the second direction.

11. The electronic device of claim 10, where in the first direction is perpendicular to the circuit board.

12. The electronic device of claim 9, wherein heat generated by the first heat source is greater than heat generated by the second heat source.

13. The electronic device of claim 9, wherein the fan defines four cutouts at four corners of the fan; the circuit board further comprises four posts; the four cutouts receive the four posts to fix the fan to the posts.

14. The electronic device of claim 13, wherein the fan defines a screw hole on a bottom of each cutout, each post defines a screw hole aligned with each corresponding screw hole of the fan.
